(19) United States
(12) Patent Application Publication
(10) Pub. No.: US 2005/0123840 A1
(43) Pub. Date: Jun. 9, 2005

(54) Mask for use in a microlithographic projection exposure apparatus

(75) Inventors: Michael Totzeck, Schwaebisch Gmuend (DE); Toralf Gruner, Aalen-Hofen (DE); Jochen Hetzler, Aalen (DE)

Correspondence Address: SUGHRUE MION, PLLC, 2100 PENNSYLVANIA AVENUE, N.W., SUITE 800, WASHINGTON, DC, 20037, US

(73) Assignee: CARL ZEISS SMT AG

(21) Appl. No.: 10/984,868

(22) Filed: Nov. 10, 2004

Related U.S. Application Data
(60) Provisional application No. 60/518,750, filed on Nov. 10, 2003.

(51) Int. Cl. G02F 1/13; G03C 5/00; G03B 27/42; G03F 9/00

(52) U.S. Cl. 430/5; 355/53; 430/311

(57) ABSTRACT

A mask (20) for use in a microlithographic projection exposure apparatus (10) has a support (28) on which a pattern of opaque structures (32) is applied. The intermediate spaces (36, 36′) remaining between the structures (32c) are filled with a liquid or solid dielectric material (38, 38′). This increases the polarisation dependency of the diffraction efficiency, so that the mask can be used as a polarizer.

### BACKGROUND OF THE INVENTION

1. Field of the Invention

The invention relates to masks for microlithographic projection exposure apparatus, such as are used for producing large-scale integrated electrical circuits and other microstructured components. The invention relates in particular to so-called amplitude masks having a support on which a pattern of opaque structures is applied.

2. Description of Related Art

Integrated electrical circuits and other microstructured components are usually produced by applying a plurality of structured layers on a suitable substrate which, for example, may be a silicon wafer. In order to structure the layers, they are first covered with a photoresist which is sensitive to a light of a particular wavelength range, for example light in the deep ultraviolet (DUV) spectral range. The wafer coated in this way is subsequently exposed in a projection exposure apparatus. A pattern of diffracting structures, which is arranged on a mask, is projected onto the photoresist with the aid of a projection lens. Since the magnification of the lens is generally less than one, such projection lenses are often also referred to as reduction lenses.

After the photoresist has been developed, the wafer is subjected to an etching process so that the layer is structured according to the pattern on the mask. The remaining photoresist is then removed from the other parts of the layer. This process is repeated until all the layers have been applied to the wafer.

One of the main aims in the development of microlithographic projection exposure apparatuses is to be able to produce structures with smaller and smaller dimensions on the wafer, so as to increase the integration density of the components to be produced. By employing a wide variety of measures, structures whose dimensions are less than the wavelength of the projection light being used can now be produced on the wafer.

One of these measures is to expediently control the polarisation state of the projection light being used. For example, it is known that when using projection lenses with high numerical apertures such as those that may be achieved with immersion lenses, the achievable contrast and therefore the minimum size of the structures to be produced depend on the polarisation direction of the projection light. This is attributable to the fact that the desired interference phenomena between various diffraction orders are commensurately more pronounced as the match between the polarisation directions is better. Complete destructive interference between two plane waves is only possible if they have the same polarisation.

With projection light which is polarised perpendicularly to the incidence plane of the projection light (s-polarisation) therefore, the interference phenomena are independent of the angle at which the various diffraction orders meet the photoresist. With projection light polarised parallel to the incidence plane (p-polarisation) however, different diffraction orders can no longer fully interfere since the diffraction orders have different polarisation directions. The interference phenomena therefore become commensurately weaker when increasing the angle, with respect to the optical axis, at which the diffraction orders meet the photoresist. This polarisation dependency, also referred to as the “vector effect”, is therefore more pronounced when the angles in question are larger. Especially with high-aperture projection lenses, there is therefore a need to avoid undesired variations in the structure widths due to the vector effect by expediently controlling the polarisation of the projection light.

The polarisation of the projection light is controlled, albeit for another purpose, in a projection exposure apparatus known from U.S. Pat. No. 6,605,395 B2. This document describes a phase mask which has birefringent material locally applied on its lower side. When linearly polarised projection light passes through the phase mask, the polarisation direction is rotated by 90°. Projection light which has passed through different regions of the phase mask will therefore vary not only with respect to the phase, but also with respect to the polarisation state. Owing to the additional degree of freedom which is obtained, the known phase mask makes it possible to produce a larger class of patterns on the wafer; this obviates the need to use a second additional mask.

### SUMMARY OF THE INVENTION

It is an object of the present invention to improve the microlithographic production of microstructured components in such a way that the polarisation of projection light, which impinges on the photoresist or another photosensitive layer, can be controlled in a straightforward way. It is a further object of the present invention to provide measures by which it is possible to avoid undesired variations in the structure width due to the aforementioned vector effect.

This object is achieved by a mask which has a support on which a pattern of opaque structures is applied. At least one intermediate space remaining between two structures is at least partially filled with a dielectric material.

The invention is based on the discovery that the polarisation dependency of the mask's diffraction efficiency can be increased significantly if the intermediate spaces between the structures are filled with a dielectric material. The term “diffraction efficiency” also includes the zeroth diffraction order, that is to say light which is not deviated by the structures. Owing to the resulting high polarisation dependency of the diffraction efficiency, the mask itself acts as a polarizer. The finer the structures on the mask are, the greater their polarising effect will be. This dependency on the structural size is advantageous since fine structures diffract the projection light more strongly, so that the aforementioned vector effect is particularly prominent with small structures.

Use of the mask as a polarizer nevertheless has other advantages, too. Specifically, the mask itself is a particularly good place for the polarisation of the projection light to be controlled. For instance, there are many attendant difficulties when a polarizer is arranged in a pupil plane of the projection lens. On the one hand, such a polarizer usually also undesirably affects the wave front of projection light passing through, so that corrective measures need to be taken. On the other hand, often there are already other optical elements in the pupil plane, so that frequently there is not enough space to install an additional polarizer. Furthermore, if the polarisation is not controlled upstream of a pupil plane of the projection lens, undesirable polarisation-dependent perturbations may already occur in optical elements positioned in this part of the lens.

Another important advantage over arranging a polarizer in a projection lens or in an illumination system, is that such a polarizer would also need to be replaced when changing the mask in order to achieve the structure-dependent polarising effect of the mask according to the invention.

Since the width of the diffraction structures, and the way in which they are arranged on the mask, is generally dictated by the layout of the structured layers to be produced on the wafer, there are only relatively few available parameters which can be selected freely within certain limits in order to maximise the polarisation dependency. In particular, these include the dielectric material which fills the intermediate spaces, but also the electrically conductive material of which the opaque structures consist, and to a certain extent their height. The widths and spacings of the structures, however, are generally fixed. By suitably choosing the parameters that are freely selectable within certain limits, the diffraction efficiency for orthogonal polarisation states can be made to differ by up to about 45%. This even holds true with structures whose characteristic dimensions are of the order of the wavelength of DUV light, for example 193 nm.

It has furthermore been shown that resonance effects can contribute to a particularly high polarisation dependency of the diffraction efficiency. Similar effects —albeit for the infrared spectral range—are mentioned in an article by H. Tamada et al. entitled “Al wire-grid polarizer using the s-polarization resonance effect at the 0.8-μm wavelength band”, Optics Letters, volume 22, No 6, pages 419 to 421. These known grids are types of wire polarizers in which the absorption or reflection for light polarised parallel to the structures is greater than for light of the same wavelength polarised perpendicular to them.

Surprisingly, however, the classical behaviour of wire polarizers may be reversed with suitably selected parameters. This means that unlike the case of conventional wire polarizers, the structures have a higher diffraction efficiency for light of a predetermined wavelength polarised parallel to the structures than for light of the same wavelength polarised perpendicularly to them. This reversal, however, does not necessarily presuppose that there is a dielectric material in the intermediate spaces between the structures. The invention therefore also relates to such masks, or in general polarising grid structures, in which this reversal happens without there needing to be a dielectric material in the intermediate spaces between the structures.

One way of finding a parameter set with which the structures exhibit such an opposite polarisation dependency, compared with conventional wire polarizers, may be to start with an initial parameter set and, on the basis of this, to calculate the diffraction efficiencies of the structures for projection light of different polarisations. To that end, it is necessary to solve the Maxwell equations on the basis of the predetermined parameter set. The parameters are then varied until the arrangement has a higher diffraction efficiency for projection light of a predetermined wavelength polarised parallel to the structures than for projection light of the same wavelength polarised perpendicularly to them.

The parameters need not necessarily be selected equally over the entire mask. For example, it may be expedient that the already high polarisation dependency of the diffraction efficiency for finer structures be increased even further by a corresponding parameter selection, in order to suppress the aforementioned vector effect even more.

### BRIEF DESCRIPTION OF THE DRAWINGS

Various features and advantages of the present invention may be more readily understood with reference to the following detailed description taken in conjunction with the accompanying drawing in which:

FIG. 1 shows a very simplified side view of a microlithographic projection exposure apparatus having a mask according to the invention;

FIG. 2 shows a detail of the mask shown in FIG. 1, in a perspective representation which is enlarged but not true to scale;

FIG. 3 shows another embodiment of a mask according to the invention, in a representation similar to FIG. 2.

### DESCRIPTION OF PREFERRED EMBODIMENTS

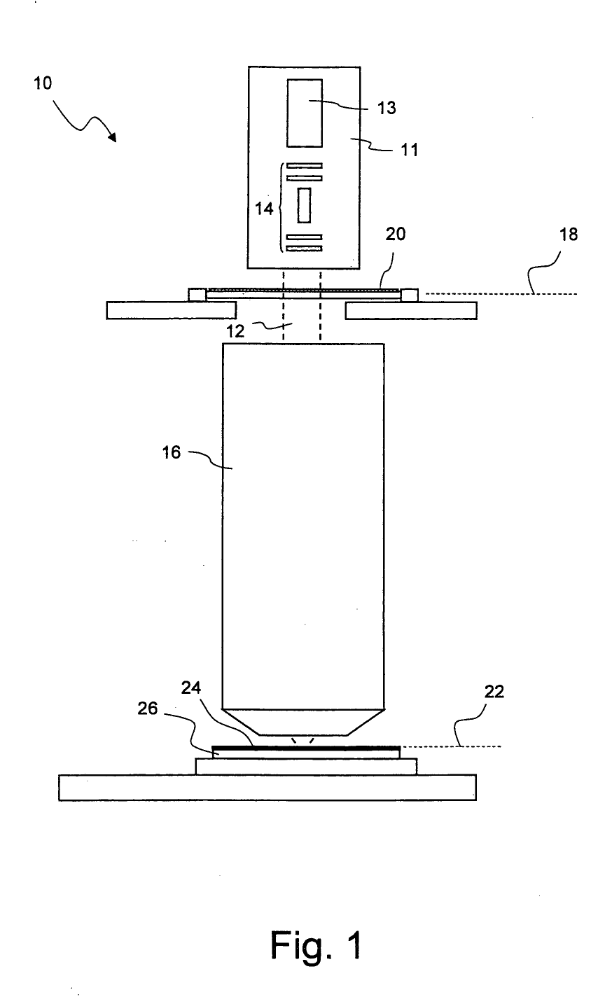

FIG. 1 shows a very simplified side view, not true to scale, of a microlithographic projection exposure apparatus denoted in its entirety by 10. The projection exposure apparatus 10 has an illumination device 11 which is used for the generation of projection light 12. To that end, the illumination system 11 comprises a light source 13 which, for example, may be a laser. The wavelength of the projection light 12 generated by the light source 13 is 193 nm in the exemplary embodiment shown, and it therefore lies in the deep ultraviolet spectral range.

The illumination system 11 furthermore contains a plurality of optical elements indicated by 14, which affect the projection light emerging from the light source 13 in various ways, for example by shaping it, mixing it and changing its angular distribution. Since the light source 13 is a laser in the exemplary embodiment which is represented, the projection light emerging from it is initially polarised linearly. When passing through the optical elements 14, however, the linear polarisation may be lost so that the polarisation light 12 emerging from the illumination system 11 is only partially polarised, or even completely unpolarised. For the sake of simplicity, it will be assumed below that the polarisation light 12 emerges completely unpolarised from the illumination system 11.

The projection exposure apparatus 10 furthermore comprises a projection lens 16 having an object plane 18. In this object plane 18 a mask 20 is displaceably arranged. In an image plane 22 of the projection lens 16, there is a photosensitive layer 24 which, for example, may be a photoresist. The photosensitive layer 24 is applied on a support 26 in the form of a silicon wafer. Since the projection exposure apparatus 10 is, to this extent, known as such in the art, there is no need to go into further details of most of its components.

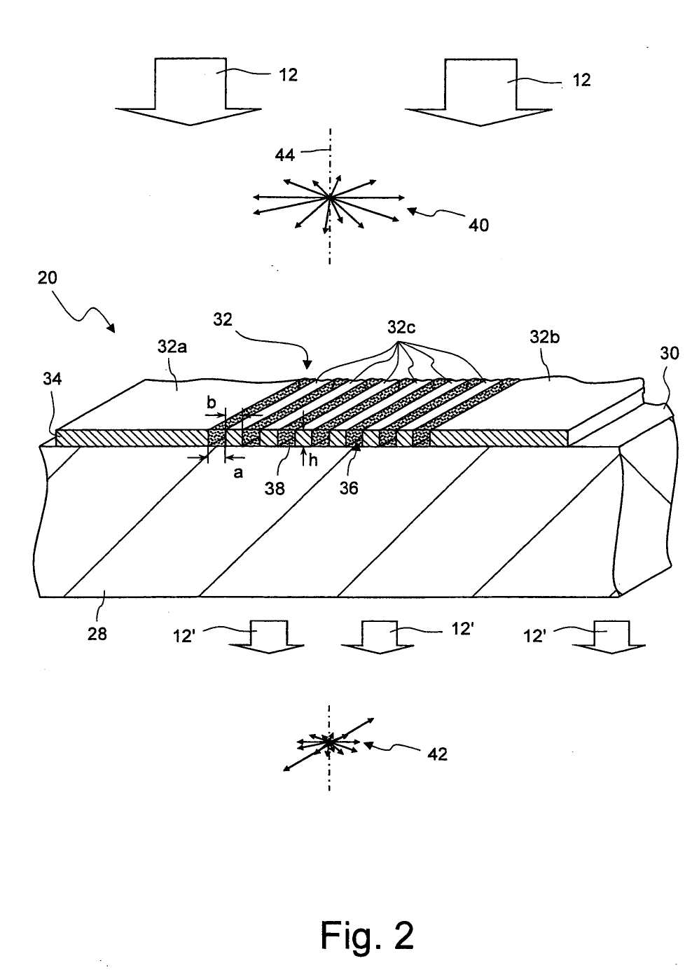

The structure of the mask 20 will be explained in more detail below with reference to FIG. 2.

FIG. 2 shows details of the mask 20 in a perspective representation which is not true to scale. The mask 20 has a support 28 consisting of a material which is transparent for the projection light 12 having a wavelength of 193 nm. Quartz glass, in particular, is suitable as a material for this wavelength.

A pattern of opaque structures 32, which is only represented by way of example here, is applied to a surface 30 of the support 28 facing the illumination system 11. In the detail shown in FIG. 2, the opaque structures 32 comprise coarser large-area structures 32a, 32b and finer bar-like structures 32c, which have an essentially rectangular cross section. The structures 32 are produced by means of a lithographically defined etching process from a layer 34 which consists of an electrically conductive material, for example chromium. Transparent intermediate spaces 36 are left between the opaque structures 32, and these are filled with a dielectric material 38. This material 38 is highly pure water in the exemplary embodiment which is represented, which is kept in the intermediate spaces 36 by adhesion forces while the mask 20 is being displaced in the object plane 18.

The width b of the bar-like structures 32c is 100 nm in the exemplary embodiment shown, the height h of the layer 34 is 110 nm and the spacing a between the neighbouring bar-like structures 32c is 200 nm. The width b of the bar-like structures 32c therefore has an order of magnitude close to the wavelength of the projection light 12.

The refractive indices of the structures 32 and of the dielectric material, the height of the layer 34 and the dimensions of the bar-like structures 32c are matched to one another so that the bar-like structures 32c have a higher diffraction efficiency for projection light 12 which is polarised along the length direction of the bar-like structures 32c than for projection light 12 polarised perpendicularly to this. This is indicated in FIG. 2 by polarisation distributions 40 and 42, respectively for the projection light 12 before and the polarisation light 12′ after passing through the mask 20. As can be seen from the polarisation distribution 40, the projection light 12 before passing through the mask 20 has a statistically varying distribution of the polarisation directions over all directions perpendicular to a propagation direction 44 of the projection light 12, as is characteristic of unpolarised light.

Since the diffraction efficiency of the bar-like structures 32c is significantly less for projection light 12 which is polarised perpendicularly to that longitudinal extent than for projection light polarised parallel to the structures 32c, the polarisation distribution 42 is obtained after the projection light has passed through the region between the coarser structures 32a, 32b. It can be seen in this that projection light 12 polarised along the length direction of the bar-like structures 32c is only attenuated comparatively little when it passes through the grid-like arrangement of the bar-like structures 32c. The diffraction efficiency is much less for polarisation components of the projection light 12 which are perpendicular to this, however, so that these components are attenuated more strongly when they pass through the mask 20.

For the mask 20 having the aforementioned material and structural parameters, when added up over all diffraction orders, it is thereby possible to obtain a 43% diffraction efficiency for projection light polarised parallel to the longitudinal extent of the structures 32c and a 6% diffraction efficiency for projection light polarised perpendicularly to this.

Because of the polarising effect of the mask 20, any ray of the projection light 12 is essentially s-polarised when it meets the photosensitive layer 24. The polarisation of the overall projection light beam is therefore also referred to as tangential. The consequence of this is that interference phenomena on and in the photosensitive layer 24 do not depend on the angle, with respect to the optical axis, at which the projection light impinges onto the photosensitive layer 24. Undesirable contrast variations due to the aforementioned vector effect are therefore substantially avoided.

It should be understood that the polarisation effect explained above occurs not only with narrow bar-like structures 32c but also with regular arrangements of coarser structures and, to a certain extent, even with individual structures. However, the polarising effect of the mask 20 decreases as the structural sizes increase.

Furthermore, not all intermediate spaces between the structures 32 need to be filled with a dielectric material. FIG. 2 shows on the right next to the structure 32b, for example, a region on the surface 30 of the support 28 where neither an opaque structure 32 nor a dielectric material 38 is applied.

Simulation calculations are preferably carried out in order to find structural and material parameters for a mask 20 with a high polarisation dependency of the diffraction efficiencies. Because, for production technology reasons, the dimensions of the structures 32 ought not to be substantially less than the wavelength of the projection light 12 in the case of short-wave projection light 12, approximation models cannot be employed for calculating the diffraction efficiencies. Instead, the Maxwell equations need to be solved for the structures 32 with the aid of numerical algorithms in these cases, so as to be able to find the polarisation-dependent diffraction efficiencies. Since such methods are known in the prior art, further details of them will not be described. Such calculations are carried out, inter alia, by using Rigorous Coupled Wave Theory (RCWA) and with the aid of the FDTD method (FDTD Finite Difference Time Domain).

If a liquid is used for the dielectric material 48, as described above, then the polarisation-dependent effect of the mask 20 can be altered by replacing the liquid by a liquid with another refractive index or changing the temperature of the liquid. Instead of a liquid dielectric material, it is nevertheless also possible to use solid materials, for example polymers or quartz glass.

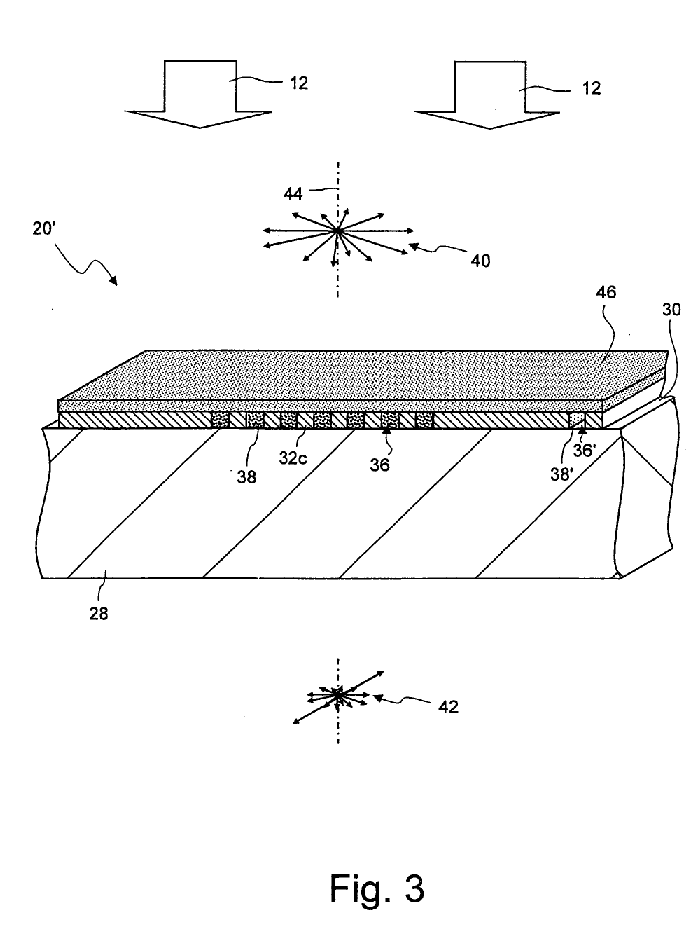

FIG. 3 shows a mask according to another embodiment in a representation similar to FIG. 2, denoted overall by 20′. In the mask 20′, there is dielectric material 38 not only in the intermediate spaces 36 between the bar-like structures 32c but also over the structures 32. This covering material is a layer of another dielectric material 46, which covers the entire surface of the mask 20′ facing the illumination system 11. For example, the material 46 may be highly pure water while the dielectric material 38 between the structures 36 is solid. The dielectric material in the intermediate spaces 34 and over the structures 32 may nevertheless be the same material, for example water or a solid dielectric material such as quartz glass.

Unlike the mask 20 shown in FIG. 2, the mask 20′ according to FIG. 3 furthermore has an intermediate space 36′ visible on the right next to the structure 32b, which is filled with a dielectric material 38′ different from the material 38 in the intermediate spaces 36. The polarisation dependency of the diffraction efficiency can expediently be adjusted locally by such a selection of different dielectric materials.

The above description of the preferred embodiments has been given by way of example. From the disclosure given, those skilled in the art will not only understand the present invention and its attendant advantages, but will also find apparent various changes and modifications to the structures and methods disclosed. It is sought, therefore, to cover all changes and modifications as fall within the spirit and scope of the invention, as defined by the appended claims, and equivalents thereof.

1. A mask for use in a microlithographic projection exposure apparatus, comprising
a support on which a pattern of opaque structures is applied,
at least one intermediate space remaining between two structures, wherein said intermediate space is at least partially filled with a dielectric material.

2. The mask according to claim 1, wherein the dielectric material is liquid.

3. The mask according to claim 1, wherein the dielectric material is solid.

4. The mask according of claim 1, wherein different intermediate spaces are at least partially filled with different dielectric materials.

5. The mask according to claim 1, wherein the dielectric material covers at least one structure.

6. The mask according to claim 5, wherein the structures are covered by a dielectric material which is different from the dielectric material located in the at least one intermediate space.

7. The mask according to claim 1, wherein the opaque structures consist of an electrically conductive material.

8. The mask according to claim 7, wherein the electrically conductive material and the structures have refractive indices and heights that are determined so that the mask has a higher diffraction efficiency for projection light of a predetermined wavelength polarised parallel to the structures than for projection light of the same wavelength polarised perpendicular to them.

9. The mask according to claim 7, wherein the height of the structures is between 50% and 150%, preferably between 75% and 125%, of the wavelength of the projection light in the dielectric material.

10. The mask according to claim 7, wherein the conductive material has a complex refractive index with a real part in the range between 0.4 and 1.0.

11. The mask according to claim 7, wherein the conductive material has a complex refractive index with an imaginary part in the range between 1.0 and 2.0.

12. A microlithographic projection exposure apparatus for the production of microstructured components, comprising:
an illumination system for the generation of projection light having a predetermined wavelength,
a mask that is exposed to the projection light and comprises:
a support on which a pattern of opaque structures is applied,
at least one intermediate space remaining between two structures, wherein said intermediate space is at least partially filled with a dielectric material,
a projection lens which projects the mask onto a photosensitive layer.

13. The projection exposure apparatus according to claim 12, wherein the projection light has a wavelength of less than 200 nm, and the projection lens has a numerical aperture of more than 0.9.

14. The projection exposure apparatus according to claim 12, wherein the mask is arranged as a polarizer in the illumination system.

15. The projection exposure apparatus according to claim 12, wherein the mask is arranged as a polarizer in the projection lens.

16. The projection exposure apparatus according to claim 14, wherein the structures are regularly distributed over a surface of the mask.

17. The projection exposure apparatus according to claim 15, wherein the structures are regularly distributed over a surface of the mask.

18. A method for the microlithographic production of a microstructured component, comprising the following steps:
a) providing a projection lens;
b) arranging a mask according to claim 1 in an object plane of the projection lens;
c) projecting the pattern applied on the mask onto a photosensitive layer, which is arranged in an image plane of the projection lens.

19. A microstructured component that is produced by a method according to claim 18.

20. A method for producing a mask, for use in a microlithographic projection exposure apparatus, which has a support on which a pattern of opaque structures consisting of an electrically conductive material is applied, said method comprising the steps of:
a) at least partially filling at least one intermediate space remaining between two structures with a dielectric material;
b) specifying a parameter set which comprises at least the wavelength of projection light used in the projection exposure apparatus, the complex refractive indices of the electrically conductive material and of the dielectric material and the height of the opaque structures;
c) rigorously calculating the diffraction efficiency of the opaque structures for projection light of different polarisation by solving the Maxwell equations on the basis of the predetermined parameter set;
d) repeating step (c) with a modified parameter set until having found a parameter set with which the opaque structures have a higher diffraction efficiency for projection light polarised parallel to the structures than for projection light polarised perpendicularly to them.
